(19) United States
(12) Patent Application Publication
(10) Pub. No.: US 2026/0293338 A1
(43) Pub. Date: Sep. 24, 2026

(54) IMAGE SENSOR HAVING A CONDUCTIVE MATERIAL LAYER

(71) Applicant: Samsung Electronics Co., Ltd., Suwon-si (KR)

(72) Inventors: Younggu Jin, Suwon-si (KR); Kyungho Lee, Suwon-si (KR)

(73) Assignee: Samsung Electronics Co., Ltd., Suwon-si (KR)

(21) Appl. No.: 19/551,304

(22) Filed: Feb. 26, 2026

(30) Foreign Application Priority Data
Mar. 19, 2025 (KR) 10 2025 0035256

(51) Int. Cl. H10F 39/00; H10F 39/18

(52) U.S. Cl. CPC H10F 39/8037; H10F 39/014; H10F 39/182; H10F 39/807; H10F 39/809; H10F 39/811

(57) ABSTRACT

An image sensor includes a substrate including pixel regions each including a photodiode; a floating diffusion region disposed in each of the pixel regions on one surface of the substrate and configured to store electric charge transferred from the photodiode; circuit elements configured to transmit a photoelectric signal according to the electric charge of the floating diffusion region; and a first interlayer insulating layer covering the floating diffusion region on the one surface of the substrate, wherein at least one of the circuit elements includes a conductive material layer disposed on the first interlayer insulating layer and including a source region and a drain region; and a gate electrode disposed between the source region and the drain region on the conductive material layer, and wherein the source region is connected to one pixel region among the pixel regions, and the drain region is connected to another pixel region.

### CROSS-REFERENCE TO RELATED APPLICATIONS

This present application claims priority and the benefit under 35 U.S.C. § 119(a)-(d) of Korean Patent Application No. 10-2025-0035256 filed on Mar. 19, 2025 in the Korean Intellectual Property Office, the entire disclosure of which is incorporated herein by reference.

### FIELD

Example embodiments of the present disclosure relate to an image sensor and more particularly to an image sensor including a conductive material layer.

### BACKGROUND

An image sensor may be a semiconductor-based sensor which may receive light and may generate an electric signal, and may include a pixel array having a plurality of pixels, and a logic circuit configured to drive the pixel array and to generate an image. Each of the pixels may include a photodiode and a pixel circuit configured to convert electric charges generated by the photodiode into an electric signal. As the number of pixels included in an image sensor increases and the size of each pixel decreases, various methods for effectively forming elements, contact plugs and interconnections disposed in each of pixels and providing a pixel circuit.

### SUMMARY

Example embodiments of the present disclosure is to provide an image sensor in which circuit elements shared in a region of a plurality of pixels as a stacked transistor.

Example embodiments of the present disclosure is to provide an image sensor which may prevent the blooming effect by blocking electric charges of a photodiode from directly leaking through a source/drain of a switching element by forming a switching element connecting floating diffusion regions of two neighboring pixel regions in a region physically separated from the photodiode.

According to example embodiments of the present disclosure, an image sensor includes a substrate including pixel regions each including a photodiode; a floating diffusion region disposed in each of the pixel regions on one surface of the substrate and configured to store electric charge transferred from the photodiode; circuit elements configured to transmit a photoelectric signal according to the electric charge of the floating diffusion region; and a first interlayer insulating layer covering the floating diffusion region on the one surface of the substrate, wherein at least one of the circuit elements includes a conductive material layer disposed on the first interlayer insulating layer and including a source region and a drain region; and a gate electrode disposed between the source region and the drain region on the conductive material layer, and wherein the source region is connected to one pixel region among the pixel regions, and the drain region is connected to another pixel region among the pixel regions.

According to example embodiments of the present disclosure, an image sensor includes a substrate including a first pixel region including a first photodiode and a second pixel region including a second photodiode; a first isolation pattern defining the first and second pixel regions in the substrate; a first floating diffusion region configured to store electric charge transferred from the first photodiode in the first pixel region on one surface of the substrate; a second floating diffusion region configured to store electric charge transferred from the second photodiode in the second pixel region on the one surface of the substrate; a source follower transistor configured to amplifying electric charge of the first and second floating diffusion regions on the one surface of the substrate and to transmit a signal; a first interlayer insulating layer covering the source follower transistor and the first and second floating diffusion regions on the one surface of the substrate; and a switching element disposed on the first interlayer insulating layer and vertically overlapping the first isolation pattern between the first pixel region and the second pixel region, wherein the switching element includes a gate electrode, and a source region and a drain region on both sides of the gate electrode, and wherein the source region and the drain region are electrically connected to the first and second floating diffusion regions, respectively.

According to example embodiments of the present disclosure, an image sensor includes a pixel array including a plurality of pixel regions arranged in a direction parallel to one surface of the substrate, each of the plurality of pixel regions including at least one photodiode in the substrate, a color filter disposed on the other surface opposite to the one surface of the substrate and at least one element disposed on the one surface; and a logic circuit configured to obtain a pixel signal from the plurality of pixel regions, wherein the pixel array includes a floating diffusion region disposed in each of the plurality of pixel regions and configured to store an electric charge transferred from the photodiode on the one surface of the substrate; the elements configured to transmit a photoelectric signal according to electric charge of the floating diffusion region; and a first interlayer insulating layer covering the floating diffusion region on the one surface of the substrate, wherein at least one of the elements includes a conductive material layer disposed on the first interlayer insulating layer and including a source region and a drain region; and a gate electrode disposed between the source region and the drain region on the conductive material layer, and wherein the source region is connected to one pixel region among the pixel regions, and the drain region is connected to another pixel region among the pixel regions.

According to example embodiments of the present disclosure, a method of manufacturing an image sensor includes forming a first isolation pattern defining pixel regions and a second isolation pattern from one surface of the substrate on the first isolation pattern in the substrate; forming transfer transistors and floating diffusion regions in each of the pixel regions on the one surface of the substrate; forming a first interlayer insulating layer covering the transfer transistors and the floating diffusion regions; and forming a thin film transistor connecting a source region and a drain region to each of the different pixel regions on the first interlayer insulating layer.

The forming the thin film transistor includes forming a conductive material layer on the first interlayer insulating layer; forming a gate insulating layer covering the conductive material layer; and forming a gate electrode on the gate insulating layer.

As the conductive material layer, a material different from the substrate may be deposited.

As the conductive material layer, oxide semiconductor or polysilicon may be deposited.

The forming the thin film transistor may further include forming a source region and a drain region by ion-implanting conductivity-type impurities on both sides of the conductive material layer using the gate electrode as a mask.

The source region may be disposed to overlap a pixel region in a vertical direction, and the drain region may be disposed to overlap the other pixel region adjacent to the one pixel region in the vertical direction.

The method further includes forming via holes exposing a portion of the one pixel region and the other pixel region in the first interlayer insulating layer; and forming contact plugs in the via holes, respectively, and forming contact plugs in each of the via holes, and the contact plugs may be in contact with the source region and the drain region, respectively.

A lower surface of the source region and the drain region may be in direct contact with an upper surface of the contact plugs.

The thin film transistor may be formed to be positioned at a level higher than a level of the one surface of the substrate.

The thin film transistor may be configured as a switching element electrically connecting the floating diffusion regions of different pixel regions to one another.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a block diagram illustrating an image sensor according to example embodiments of the present disclosure;

FIG. 2 is a diagram illustrating a pixel circuit according to example embodiments of the present disclosure;

FIG. 3 is a diagram illustrating arrangement of pixels of the image sensor illustrated in FIG. 2;

FIG. 4 is a plan diagram illustrating a pixel region of one of the pixels illustrated in FIG. 3;

FIG. 5 is a cross-sectional diagram illustrating the image sensor illustrated in FIG. 4;

FIG. 6 is an enlarged diagram illustrating a portion illustrated in FIG. 5;

FIG. 7, FIG. 8 and FIG. 9 are cross-sectional diagrams illustrating an image sensor according to example embodiments of the present disclosure;

FIG. 10 is a circuit diagram illustrating a pixel circuit according to example embodiments of the present disclosure;

FIG. 11 is a plan diagram illustrating a pixel circuit according to example embodiments of the present disclosure;

FIG. 12 is a cross-sectional diagram illustrating the image sensor in FIG. 11;

FIG. 13 is a cross-sectional diagram illustrating an image sensor according to example embodiments of the present disclosure; and FIG. 14A, FIG. 14B, FIG. 14C, and FIG. 14D are cross-sectional diagrams illustrating a method of manufacturing an image sensor illustrated in FIG. 5.

### DETAILED DESCRIPTION

Hereinafter, embodiments of the present disclosure will be described as follows with reference to the accompanying drawings.

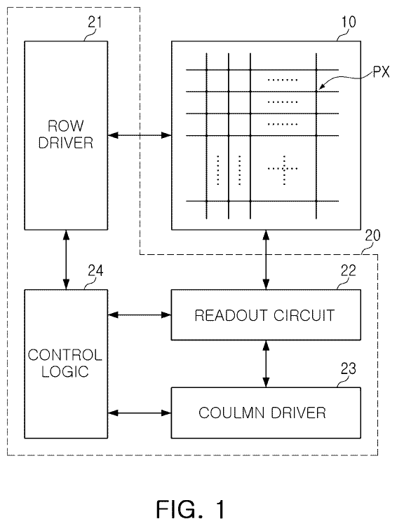

FIG. 1 is a block diagram illustrating an image sensor according to example embodiments.

Referring to FIG. 1, the image sensor 1 may include a pixel array 10 and a logic circuit 20.

The pixel array 10 may include a plurality of pixels PX disposed in an array form along a plurality of rows and a plurality of columns. Each of the plurality of pixels PX may include at least one photodiode configured to generate an electric charge in response to light, and a pixel circuit configured to generate a pixel signal corresponding to electric charge generated by the photodiode. The photodiode may include a photodiode formed of a semiconductor material, and/or an organic photodiode formed of an organic material.

For example, the pixel circuit may include a floating diffusion region, a transfer transistor, a reset transistor, a source follower transistor, and a select transistor. In example embodiments, the configuration of the pixels PX may vary. For example, each of the pixels PX may include an organic photodiode including an organic material, or may be implemented as a digital pixel. When pixels PX are implemented as digital pixels, each of the pixel PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, and a control logic 24. The row driver 21 may drive the pixel array 10 as a row lines unit. For example, the row driver 21 may generate a transfer control signal for controlling a transfer transistor of the pixel circuit, a reset control signal for controlling a reset transistor, and a select control signal for controlling a source follower transistor, and may input the signals to the pixel array 10 by a row line unit.

The readout circuit 22 may include a correlated double sampler (CDS) and an analog-to-digital converter (ADC). The correlated double samplers may be connected to the pixels PX through column lines. The correlated double samplers may read a pixel signal from the pixels PX connected to a row line selected by a row line select signal of the row driver 21 through column lines. An analog-to-digital converter may convert the pixel signal detected by the correlated double sampler into a digital pixel signal and may transfer the signal to the column driver 23.

The column driver 23 may include a latch or a buffer circuit and an amplifier circuit which may temporarily store a digital pixel signal, and may process a digital pixel signal received from the readout circuit 22. The row driver 21, the readout circuit 22, and the column driver 23 may be controlled by the control logic 24. The control logic 24 may include a timing controller for controlling operation timings of the row driver 21, the readout circuit 22, and the column driver 23.

Among the pixels PX, pixels PX disposed in the same position in the horizontal direction may share the same column line. For example, the pixels PX disposed in the same position in the vertical direction may be simultaneously selected by the row driver 21 and may output a pixel signal through column lines. In example embodiments, the readout circuit 22 may simultaneously obtain pixel signals from the pixels PX selected by the row driver 21 through the column lines. The pixel signal may include a reset voltage and a pixel voltage, and the pixel voltage may be configured as a voltage in which electric charge generated by response to light in each of the pixel PX is reflected in the reset voltage.

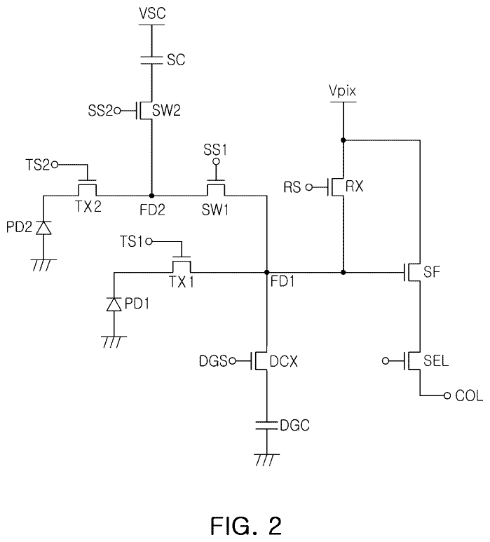

FIG. 2 is a diagram illustrating a pixel circuit of an image sensor according to example embodiments.

Referring to FIG. 2, a unit pixel PX of an image sensor 1 according to example embodiments may include at least two photodiodes PD1 and PD2, and may output an electric signal using electric charge generated by the first photodiode PD1, and may output an electric signal using electric charge generated by the second photodiode PD2. Operation of active elements included in the pixel PX may be controlled by a controller included in the image sensor 1.

The image sensor 1 may include a first switching element SW1, a second switching element SW2, a storage capacitor SC, a reset transistor RX, first and second transfer transistors TX1 and TX2, a source follower transistor SF, a dual conversion gain transistor DCG, and a select transistor SEL. The first photodiode PD1 may be connected to the first floating diffusion region FD1 through the first transfer transistor TX1. The second photodiode PD2 may be connected to the second floating diffusion region FD2 through the second transfer transistor TX2.

The first transfer transistor TX1 may transfer electric charges accumulated in the first photodiode PD1 to the first floating diffusion region FD1 based on a first transfer control signal TS1 transferred from the row driver 21. The first photodiode PD1 may generate electrons as a main electric charge carrier. The source follower transistor SF may operate as a source follower buffer amplifier by electric charges accumulated in the first floating diffusion region FD1. The source follower transistor SF may amplify electric charges accumulated in the first floating diffusion region FD1 and may transfer electric charges to the source follower transistor SF.

The source follower transistor SF may operate by the select control signal input by the row driver 21 and may perform switching and addressing operations. When the select control signal is applied from the row driver 21, a voltage may be output to the column line COL connected to the source follower transistor SF. The voltage may be detected by the column driver 23 and the readout circuit 22 connected to the column line COL. The column driver 23 and the readout circuit 22 may detect a reset voltage when electric charge is not accumulated in the first floating diffusion region FD1, and may detect a pixel voltage in a state in which electric charge is accumulated in the first floating diffusion region FD1. In example embodiments, the image sensor may generate an image by calculating a difference between the reset voltage and the pixel voltage.

The second photodiode PD2 may be connected to the second switch element SW2 and the storage capacitor SC through the second transfer transistor TX2. Similarly to the first photodiode PD1, the second photodiode PD2 may also generate electrons as a main electric charge carrier. Electric charge generated by the second photodiode PD2 may move to the storage capacitor SC when the second transfer transistor TX2 is turned on.

The storage capacitor SC may be configured as an element for storing electric charge generated by the second photodiode PD2. The storage capacitor SC may be a stacked-type capacitor and may be implemented as a MIM capacitor, a PIP capacitor, or the like. The second power voltage VSC connected to the storage capacitor SC may be a value smaller than a value of the first power voltage V_{PIX} of the entire pixel circuit. However, example embodiments thereof are not limited thereto.

The storage capacitor SC may store electric charge in response to the amount of electric charge generated by the second photodiode PD2 and operation of the second transfer transistor TX2.

The first switch element SW1 may be connected between the second floating diffusion region FD2 and the first floating diffusion region FD1, and electric charge of the storage capacitor SC may be transferred to the first floating diffusion region FD1, or electric charge of the second floating diffusion region FD2 may be transferred to the first floating diffusion region FD1 by turning on/off operations of the first switch element SW1. To adjust a conversion gain of electric charge generated by the first photodiode PD1 or capacitance of the pixel, a dual conversion gain transistor DCG and a dual conversion gain capacitor DGC may be further included. The dual conversion gain transistor DCG may be turned on in response to the control signal DGS and may function as the dual conversion gain capacitor DGC configured to store electric charge of the first floating diffusion region FD1.

The circuit elements included in each of the pixel PX may be distributed in two pixel regions physically isolated from one another. Accordingly, it may be understood that circuit elements of the two pixel regions may be shared. In example embodiments illustrated in FIG. 2, the plurality of first photodiode PD1 and the second photodiode PD2 may share a column line COL. Accordingly, while the first pixel voltage corresponding to electric charge of the plurality of first photodiode PD1 is output to the column line COL, the second photodiode PD2 may be isolated from the column line COL. For example, while the first pixel voltage is output to the column line COL, the first switch element SW1 may be turned off such that the second photodiode PD2 may be isolated from the column line COL.

To generate the first pixel voltage using electric charge of the first photodiode PD1 and may output the voltage to the column line COL, the first transfer transistor TX1 may be turned on such that electric charge generated by the first photodiode PD1 may be accumulated in the first floating diffusion region FD1.

Similarly, while the second pixel voltage corresponding to electric charge of the second photodiode PD2 is output to the column line COL, the plurality of the first photodiode PD1 may be isolated from the column line COL. For example, while the second pixel voltage is output to the column line COL, the first transfer transistor TX1 may be turned off such that the plurality of the first photodiode PD1 may be isolated from the column line COL.

To generate the second pixel voltage and output the voltage to the column line COL, the first switching element SW1 and the second switching element SW2 may be turned on and the second floating diffusion region FD2 and the first floating diffusion region FD1 may be connected to one another. Electric charge generated by the second photodiode PD2 and stored in the storage capacitor SC may be accumulated in the first floating diffusion region FD1 and the second floating diffusion region FD2 and may be converted into a voltage by the source follower transistor SF.

Also, the first switch element SW1 may be turned on and the second switching element SW2 may be turned off such that electric charge of the second photodiode PD2 may be converted into a voltage by the source follower transistor SF.

Also, the first switching element SW1 may be turned off, and the second switching element SW2 may be turned off such that electric charge of the first photodiode PD1 may be converted into a voltage by the source follower transistor SF. The voltages converted at each step may be combined to produce a second pixel voltage of the second photodiode PD2.

In example embodiments, the second photodiode PD2 may be used for sensing a flickering external light source, or for improving a dynamic range of the image sensor 1. To improve the dynamic range of the image sensor 1, when the first pixel voltage generated by electric charge of a plurality of first photodiode PD1s is output multiple times, the second pixel voltage generated by electric charge of the second photodiode PD2 may be output only once.

An area of the first photodiode PD1 may be relatively greater than an area of the second photodiode PD2. In example embodiments, an image accurately representing a flickering external light source is generated using electric charges generated by the second photodiode PD2, and electric charge generated by the plurality of first photodiode PD1 may be used to generate a general image. Also, by controlling the exposure time for each of the first photodiode PD1 and the second photodiode PD2 to receive light and transmitting a voltage to one column line COL through a shuttering method, the dynamic range and image quality of the image sensor may be improved.

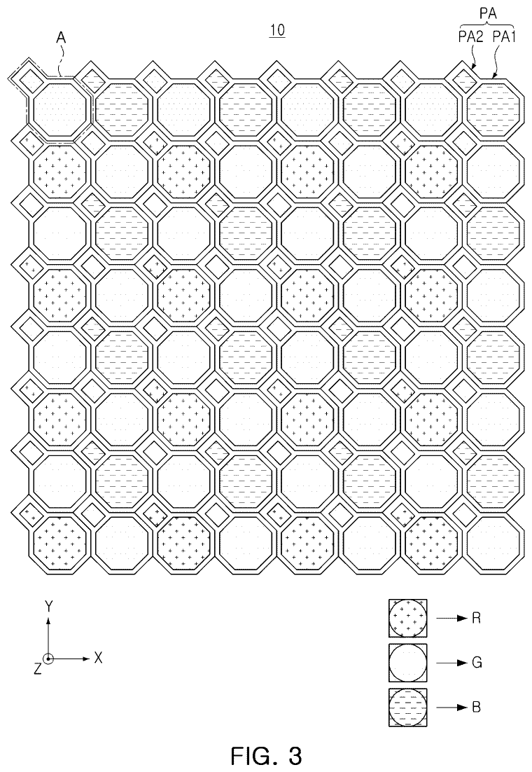

The pixel PX in FIG. 2 may be implemented as unit pixel regions having the arrangement as in FIG. 3.

Referring to FIG. 3, a pixel array 10 of an image sensor 1 in example embodiments may include a plurality of unit pixels PX, and a pixel region PA assigned to each of the pixel PX may include a first pixel region PA1 and a second pixel region PA2. For example, the pixel array 10 may include the first pixel region PA1 which is a general pixel and a second pixel region PA2 which is an autofocus pixel. A position and arrangement of the second pixel region PA2 may be varied, but, as in FIG. 2, the second pixel region PA2 may extend from one side surface of the first pixel region PA1. Specifically, when the first pixel region PA1 has a polygonal shape having a space therein, for example, an octagonal shape, the second pixel region PA2 may be implemented as a polygonal shape sharing one side thereof. Accordingly, a boundary isolation pattern 103a may be disposed between the first pixel region PA1 and the second pixel region PA2, and the boundary isolation pattern 103a may be the same as a first isolation pattern 103 surrounding the first pixel region PA1 and the second pixel region PA2. An area of the first pixel region PA1 may be greater than an area of the second pixel region PA2, and accordingly, a size of the first photodiode PD1 included therein may also be greater than a size of the second photodiode PD2.

When the second pixel region PA2 extends to one surface of the first pixel region PA1, the second pixel region PA2 may have a slope in the diagonal d1 direction, not in the X-direction or the Y-direction. Accordingly, the second pixel region PA2 may be disposed in a spacing between two neighboring first pixel regions PA1, but the position of the second pixel region PA2 is not limited to the illustrated example in FIG. 3, and may be varied.

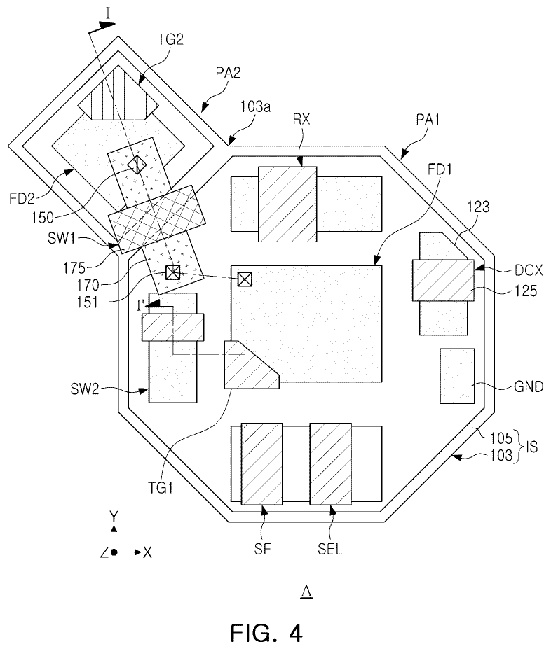

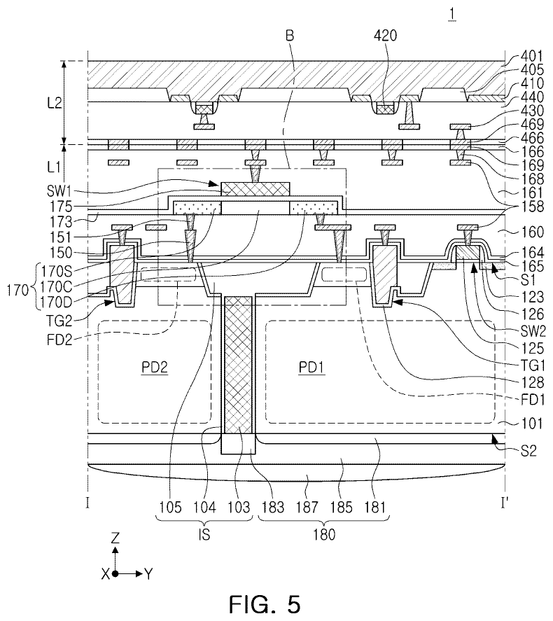

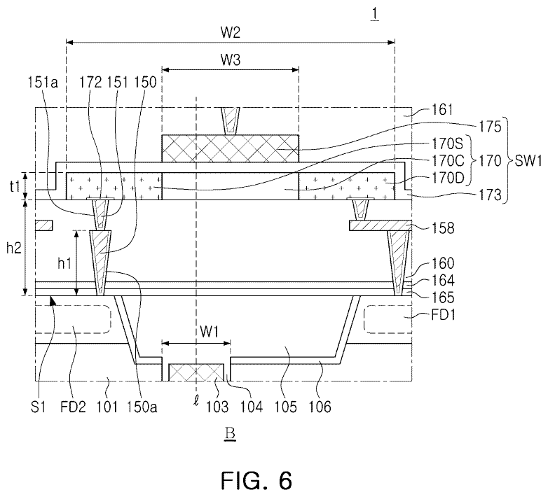

FIG. 4 is a plan diagram illustrating a pixel region of one of the pixels illustrated in FIG. 3. FIG. 5 is a cross-sectional diagram illustrating the image sensor illustrated in FIG. 4. FIG. 6 is an enlarged diagram illustrating a portion illustrated in FIG. 5, illustrating region “B” in FIG. 5.

An image sensor 1 may include a first structure L1 corresponding to a pixel array 10 and a second structure L2 corresponding to a logic circuit 20 bonded thereto.

In the first structure L1 of pixel array 10, a first isolation pattern 103 may be disposed between pixel regions PA defining unit pixels PX, and each of the pixel regions PA may include a first pixel region PA1 having a polygonal shape, for example, a first pixel region PA1 having an octagonal shape and a second pixel region PA2 having a quadrangular shape which shares one side implemented as the boundary isolation pattern 103a.

The first pixel region PA1 may occupy an area greater than the second pixel region PA2, and may include floating diffusion regions FD1 and FD2, respectively, transfer gates TG1 and TG2 of the transfer transistors TX1, TX2, and gate structures 125 and 126 of a plurality of transistors in the pixel regions PA1 and PA2. A ground region GND may be disposed in the first and second pixel regions PA1 and PA2.

The first and second floating diffusion regions FD1 and FD2 in the first and second pixel regions PA1 and PA2 may be doped with first conductivity-type impurities, and electric charges generated by the first and second photodiodes PD1 and PD2 may be accumulated therein. For example, the first conductivity-type impurities may be N-type impurities.

The first and second floating diffusion regions FD1 and FD2 may be connected to at least one contact plug 150, and the first and second floating diffusion regions FD1 and FD2 may be adjacent to the transfer gates TG1 and TG2. The first and second transfer gates TG1 and TG2 may be adjacent to the first and second photodiodes PD1 and PD2 respectively formed on an inner side of the first isolation pattern 103 in the first direction (Z-direction).

When a first bias voltage is input to the first and second transfer gates TG1 and TG2, electric charges generated by the first and second photodiodes PD1 and PD2 may not move to the floating diffusion regions FD1 and FD2. When the voltage of the first and second transfer gates TG1 and TG2 increases to a second bias voltage higher than the first bias voltage, electric charges generated by the first and second photodiodes PD1 and PD2 may move to the floating diffusion regions FD1 and FD2. For example, the first bias voltage may be a negative voltage, and the second bias voltage may be a positive voltage. An absolute value of the first bias voltage may be smaller than an absolute value of the second bias voltage.

In example embodiments illustrated in FIG. 4, the first and second floating diffusion regions FD1 and FD2 may extend in the second direction (X-direction) and/or the third direction (Y-axis direction). The first floating diffusion region FD1 may extend to have a quadrangular shape, but example embodiments thereof is not limited thereto, and the first floating diffusion region FD1 may be disposed to ensure the largest area in the first pixel region PA1. The second floating diffusion region FD2 may be disposed to ensure the largest area in the second pixel region PA2, and may have a shape similar to a shape of the second pixel region PA2. Accordingly, the first and second floating diffusion regions FD1 and FD2 may have different shapes and different areas. However, the shapes of the first and second floating diffusion regions FD1 and FD2 are not limited thereto, and may be in example embodiments.

The first transfer gate TG1 connected to the first photodiode PD1 may be disposed in the first pixel region PA1, and the second transfer transistor TG2 connected to the second photodiode PD2 may be disposed in the second pixel region PA2.

Among the transistors, a second switch element SW2, a reset transistor RX, a source follower transistor SF, a select transistor SEL, and a dual conversion gain transistor DCX may be disposed in the first pixel region PA1, and circuit elements may not be disposed in the second pixel region PA2, or a smaller number of circuit elements may be disposed than in the first pixel region PA1. The transistors other than the first and second transfer gates TG1 and TG2 may include gate structures 125, 126, and 128 and active regions 123, disposed on both sides of the gate structures 125, 126, and 128. An area of each of the active regions 123 may be smaller than that of the first and second floating diffusion regions FD1 and FD2. This may be because the area of the first and second floating diffusion regions FD1 and FD2 in which electric charges generated by each photodiode PD1 and PD2 are accumulated may need to be relatively larger. Each of the pixel regions PA1 and PA2 may further include a second isolation pattern (STI: Shallow trench isolation) 105 to isolate the active regions 123.

The active region 123 for the ground region GND may be further included in each of the pixel regions PA1 and PA2. The ground region GND may be isolated from the first and second floating diffusion regions FD1 and FD2 and transistors, and may not be in contact with the first and second transfer gates TG. Also, the ground region GND may be doped with second conductivity-type impurities different from those of the first and second floating diffusion regions FD1 and FD2 and the active regions 123.

Contact plugs 150 and 151 may be disposed in the first and second transfer gates TG1 and TG2, the first and second floating diffusion regions FD1 and FD2, the gate structures 125, 126, and 128, and the active regions 123 and the ground region GND.

The substrate 101 may be configured as a semiconductor substrate. For example, the substrate 101 may be formed of a semiconductor material, for example, a single crystal silicon substrate.

The substrate 101 may include one surface S1 and the other surface S2 opposing the one surface S1, and the first and second photodiodes PD1 and PD2 may be formed in the substrate 101 in the two first and second pixel regions PA and PA2 between the one surface S1 and the other surface S2, respectively. The first and second photodiodes PD1 and PD2 may be adjacent to the first and second transfer gates TG1 and TG2 in the Z-direction perpendicular to one surface S1 of the substrate 101, respectively.

An optical unit 180 may be disposed on the other surface S1 of the substrate 101 adjacent to the first and second photodiodes PD1 and PD2 in the Z-direction, the vertical direction. The optical unit 180 may include a color filter 181, a grid structure 183, a planarization layer 185, and a microlens 187. The color filter 181 may be isolated from the color filters of other adjacent pixels by the grid structure 183, and may transmit light of a predetermined wavelength band. The microlens 187 may refract light incident to the pixel PX and may focus light on the photodiodes PD1 and PD2. The first and second photodiodes PD1 and PD2 may generate electric charges in response to light passing through the optical unit 180.

Circuit elements may be disposed on one surface S1 of the substrate 101, which is one side of the first and second photodiodes PD1 and PD2 in the Z-direction, the vertical direction. Accordingly, the optical unit 180 and circuit elements may be disposed on both sides of the first and second photodiodes PD1 and PD2 in the first direction, the Z-direction.

The first and second photodiodes PD1 and PD2 in the substrate 101 may be isolated from one another, and a first isolation pattern 103 including surfaces of an octagonal prism and a quadrangular prism in the substrate 101 may be disposed. The first isolation pattern 103 may include a boundary isolation pattern 103a isolating the first pixel region PA1 and the second pixel region PA2 forming one pixel region PA from one another. The boundary isolation pattern 103a may be formed as one side, but example embodiments thereof are not limited thereto, and the boundary isolation pattern 103a may be understood as a first isolation pattern 103 shared between the first and second pixel regions PA1 and PA2 in the pixel region PA.

The first isolation pattern 103 may include a conductive material, for example, a semiconductor material, in the central region, and may include a semiconductor material including impurities having a second conductivity-type different from the first conductivity-type.

A liner may be disposed by surrounding the conductivity-type material, and a trench insulating layer 104 may be disposed between the liner and the substrate 101. Accordingly, the conductivity-type material in the first isolation pattern 103 may be in an electrically insulating state with the substrate 101. When the conductivity-type material is included in the first isolation pattern 103, the ability to collect electric charge of the photodiodes PD1 and PD2 may be improved when a black current flows. The substrate insulating region may be further included between the first and second photodiodes PD1 and PD2 and the trench insulating layer 104, but example embodiments thereof are not limited thereto.

A second isolation pattern 105 (STI) defining the active regions 123 and the first and second floating diffusion regions FD1 and FD2 of the circuit elements may be disposed from one surface S1 of the substrate 101 in the substrate 101.

The second isolation pattern 105 may be formed by removing the entire surface S1 of the substrate 101 to a predetermined depth, other than the region in which the active region 123 of the circuit elements is disposed, and the region in which the first and second floating diffusion regions FD1 and FD2 are disposed, and stacking an insulating material.

The second isolation pattern 105 may also be disposed on the first isolation pattern 103. As illustrated in FIG. 5, the second isolation pattern 105 may be aligned in the Z-direction on the first isolation pattern 103 and may form an PD isolation pattern IS partitioning each pixel region PA, and the PD isolation pattern IS may also partition the first and second pixel regions PA1 and PA2. The second isolation pattern 105 on the first isolation pattern 103 may be disposed to have a width greater than a first width W1 of the first isolation pattern 103, and an upper portion of the first isolation pattern 103 may have a lower width greater than the first width W1.

An upper surface of the second isolation pattern 105 may be substantially coplanar with one surface S1 of the substrate 101, but example embodiments thereof are not limited thereto, and the upper surface may be coplanar with an upper surface of the gate insulating layer 128.

The second isolation pattern 105 may have a width decreasing from an upper surface to a lower surface, and accordingly, the second isolation pattern 105 may have an inclined side surface. The second isolation pattern 105 may include a liner 106 surrounding a side surface and a lower surface, may bury a trench of the second isolation pattern 105 on the liner 106 and an insulating material may be disposed. The insulating material may be a material such as a silicon oxide film, a silicon oxynitride film, or a silicon oxycarbonate film. In this case, in a PD isolation pattern IS in which the second isolation pattern 105 and the first isolation pattern 103 extend in the Z-direction, the liner 106 may not be disposed on a bottom surface of the second isolation pattern 105 in contact with an upper portion of the first isolation pattern 103, but example embodiments thereof are not limited thereto.

As described above, the first and second pixel regions PA1 and PA2 may include first and second photodiodes PD1 and PD2, first and second floating diffusion regions FD1 and FD2 as one surface S1 of the substrate 101, and first and second transfer gates TG1 and TG2 adjacent to the first and second floating diffusion regions FD1 and FD2, respectively.

In the first pixel region PA1, transistors, which are circuit elements, may be disposed, and the gate electrode 125 of each of the transistors may include a semiconductor material, for example, silicon, germanium, or a combination thereof. The gate electrode 125 may include a conductive material layer doped with N-type or P-type, or may also include an undoped layer.

The first and second floating diffusion regions FD1 and FD2 may include a plurality of regions doped with impurities at different concentrations, but example embodiments thereof are not limited thereto. When a plurality of regions are included, the regions may be doped at higher concentrations in a direction away from the first and second transfer transistors TG1 and TG2.

The first and second transfer transistors TG1 and TG2 may include a transfer gate electrode, a gate insulating layer 128, and a transfer gate spacer (not illustrated). The transfer gate electrode may be formed of a conductive material such as polysilicon, metal, or metal silicide, and the first bias voltage and the second bias voltage described above may be applied to the transfer gate electrode. The transfer gate insulating layer 128 may be disposed between the transfer gate electrode and the substrate 101. The transfer gate electrode may include a multilayer structure, and the multiple layers may have different shapes. For example, the lower electrode layer may be disposed between the upper electrode layer and the first and second photodiodes PD1 and PD2 in the first direction, and may have a width decreasing toward the first and second photodiodes PD1 and PD2. The lower electrode layer may be disposed below one surface S1 of the substrate 101 and may be buried in the substrate 101, and the upper electrode layer may have a region disposed above one surface S1 of the substrate 101. The transfer gate insulating layer 128 may be formed along an interfacial surface between the transfer gate electrode and the substrate 101. The transfer gate spacer may be disposed between the first and second floating diffusion regions FD1 and FD2 and the upper electrode layer.

The gate structures 125, 126, and 128 of transistors other than the first and second transfer gates TG1 and TG2 may have shapes different from those of the transfer gates TG1 and TG2. The gate structures 125, 126, and 128 of the transistor may be formed on the substrate 101, and may include the gate electrode 125, the gate insulating layer 128, and the gate spacer 126.

The active region 123 may be disposed on both sides of the gate structures 125, 126, and 128 of the transistors other than the transfer gates TG1 and TG2, and may form each of the source region and the drain region S/D. The active region 123 may be formed by injecting first conductivity-type impurities to a predetermined depth on one surface S1 of the substrate 101.

As an example of transistors other than the first and second transfer gates TG1 and TG2, in a reset transistor RX, a source follower transistor SF, a select transistor SEL, a dual conversion gain transistor DCG, and/or a second switching element SW2 disposed in the first pixel region PA1, the active region 123 of one surface S1 of the substrate 101 may be included in the source/drain region S/D on both sides of the gate structures 125, 126, and 128.

The areas of the transistors other than the first and second transfer gates TG1 and TG2 may be different, but the heights of the gate structures 125, 126, and 128 may be substantially the same and may include the same material.

The substrate insulating layer 165 and the upper insulating layer 164 may be disposed while covering the transfer gates TG1 and TG2 and the gate structure 125, 126, and 128, and the first interlayer insulating layer 160 may be disposed thereon.

The substrate insulating layer 165 may be conformally formed on one surface S1 of the substrate 101. The substrate insulating layer 165 may conformally cover a lower portion of the transfer gates TG1 and TG2, and gate structure 125, 126, and 128 and the substrate 101 on the transfer gates TG1 and TG2, gate structure 125, 126, and 128. The substrate insulating layer 165 may include silicon oxide or a low-k material.

The substrate insulating layer 165 may conformally cover the transfer gates TG1 and TG2, gate structure 125, 126, and 128 of each circuit element, for example, the transfer transistors TG1 and TG2, the gate electrodes 125, the gate spacers 126 and the exposed substrate 101.

An upper insulating layer 164 may be disposed on the substrate insulating layer 165. The upper insulating layer 164 may include a material different from that of the substrate insulating layer 165 and may conformally cover the circuit elements and the exposed substrate 101 so as to have a thickness greater than that of the substrate insulating layer 165. The upper insulating layer 164 may include silicon nitride, silicon oxynitride or a low-k material. The upper insulating layer 164 may be formed of a material different from that of the substrate insulating layer 165, such that the upper insulating layer 164 may function as an etching stop layer during a process.

The substrate insulating layer 165 and the upper insulating layer 164 may have different functions, and by including different materials, the substrate insulating layer 165 and the upper insulating layer 164 may protect the lower circuit element and the semiconductor substrate 101. The total thickness of the substrate insulating layer 165 and the upper insulating layer 164 may satisfy 30 nm to 50 nm, and preferably 30 nm to 40 nm. Also, the upper insulating layer 164 may have the largest thickness within the above thickness.

A first interlayer insulating layer 160 may be provided on the substrate 101. The first interlayer insulating layer 160 may cover the gate electrodes 125 of the transfer gates TG1 and TG2, the source follower transistor SF, the reset transistor RX, the dual conversion gain transistor DCG, and the select transistor SEL on the upper insulating layer 164, and the substrate 101 therebetween. The first interlayer insulating layer 160 may include at least one single film of a silicon oxide (SiO), a silicon nitride (SiN), a silicon oxynitride (SiON), and a porous low-k film, or a multi-film structure thereof.

The first interlayer insulating layer 160 may be formed to have a predetermined thickness, may have a flat upper surface, and may have a second height h2 from one surface S1 of the substrate 101 to an upper surface of the first interlayer insulating layer 160 by the thickness of the first interlayer insulating layer 160.

For electrical connection with the first and second floating diffusion regions FD1 and FD2, the active region 123, and the gate electrodes 125, the contact plugs 150 and 151 may penetrate the substrate insulating layer 165 and the upper insulating layer 164, and the interlayer insulating layer 160 and may be connected to upper surfaces of the first and second floating diffusion regions FD1 and FD2, the active region 123, and the gate electrodes 125.

The contact plugs 150 and 151 may be disposed on a side surface and a bottom surface of the diffusion barriers 150a and 151a, and a metal material may be buried in the diffusion barriers 150a and 151a.

Diffusion barriers 150a and 151a may be TiN, TaN, or the like, and contact plugs 150 and 151 may include a conductive material such as W, Al, and Cu.

The first switching element SW1 may be spaced apart from one surface S1 of the substrate 101 on the first interlayer insulating layer 160.

The first switching element SW1 may have a shape of a thin film transistor (TFT) and may include a conductive material layer 170 including a material different from that of the substrate 101.

The first switching element SW1 may be disposed on an upper surface of the first interlayer insulating layer 160, may be spaced apart from the substrate 101 in the Z-direction, and may be physically spaced apart from the first and second photodiodes PD1 and PD2 in the substrate 101.

The first switching element SW1 may be configured as a switching element connecting the first floating diffusion region FD1 to the second floating diffusion region FD2 when viewed on the circuit. Specifically, the first switching element SW1 may be configured a transistor, and the source region 170S may be connected to the second floating diffusion region FD2 of the second pixel region PA2, and the drain region 170D may be connected to the first floating diffusion region FD1 of the first pixel region PA1.

In the first switching element SW1, the source region 170S and the drain region 170D may be connected to the first pixel region PA1 and the second pixel region PA2, respectively, and may electrically connect the two pixel regions PA1 and PA2 to one another.

By forming the first switching element SW1 to be spaced apart from the substrate 101, the blooming effect in which excessive photoelectric charges generated by the first photodiode PD1 in the substrate 101 pass through the substrate 101 and are directly injected into the source region 170S may be prevented when turned on by the gate voltage but also in a turned-off state.

By disposing the first switching element SW1 connecting the two pixel regions PA1 and PA2 to be spaced from the substrate 101, reliability degradation due to electric charges in the substrate 101 may be prevented.

To this end, the conductive material layer 170 may be disposed on the first interlayer insulating layer 160.

The conductive material layer 170 may be disposed to have a second length W2 while crossing the PD isolation pattern IS between the first and second pixel regions PA1 and PA2 as illustrated in FIG. 4, one end may be disposed on the first pixel region PA1, and the other end may be disposed on the second pixel region PA2.

When the conductive material layer 170 has a quadrangular shape, for example, a rectangular shape, crossing the PD isolation pattern IS, the conductive material layer 170 may cross the PD isolation pattern IS such that one end and the other end may be disposed on different pixel regions PA1 and PA2. Particularly, the conductive material layer 170 may cover the first width W1 of the boundary isolation pattern 103a among the first isolation pattern 103 included in the PD isolation pattern IS. In this case, the configuration of covering the first width W1 may indicate that the center 1 of the first width W1 and the center of the second length W2 of the conductive material layer 170 may be coaxial, and also that the second length W2 may cover the first width W1.

The conductive material layer 170 may have a first thickness t1 and may have a flat upper surface and a flat lower surface. The first thickness t1 may be equal to or less than the thickness of the active region 123 of the substrate 101, but example embodiments thereof is not limited thereto.

The conductive material layer 170 may include a material different from that of the substrate 101, and for example, the conductive material layer 170 may include at least one of IGZO, ZnO, In2O3, TiO2, or the like, as an oxide semiconductor, or may include polysilicon or graphene. When the conductive material layer 170 includes graphene, the conductive material layer 170 may be implemented to have a thickness less than when the conductive material layer 170 includes a different material.

The conductive material layer 170 may include a channel portion 170C, which is a portion corresponding to the upper gate electrode 175, and overlapping a lower portion of the gate electrode 175, and a source portion 170S and a drain portion 170D disposed on both sides of the channel portion 170C.

Here, the source portion 170S and the drain portion 170D may be portions highly doped with impurities, and may be doped with, for example, N-type or P-type impurities. In this doping process, the gate electrode 175 may function as a doping mask. Doping may be performed on an upper surface to a lower surface of the source portion 170S and the drain portion 170D.

An upper gate insulating layer 173, which is an insulating film, may be formed on the conductive material layer 170, and may be substantially formed along an upper surface of the first interlayer insulating layer 160. The upper gate insulating layer 173 may be formed of an inorganic insulating material, for example, silicon oxide or silicon nitride.

A gate electrode 175 corresponding to the channel portion 170C may be formed on the upper gate insulating layer 173. The gate electrode 175 may function as a top gate electrode 175. The gate electrode 175 may have a third width W3 smaller than the second length W2, and may extend in a direction perpendicular to the conductive material layer 170 as illustrated in FIG. 4, but example embodiments thereof is not limited thereto.

A second interlayer insulating layer 161 may be disposed on the gate electrode 175.

The second interlayer insulating layer 161 may include a material substantially the same as that of the first interlayer insulating layer 160, and upper interconnections 158 and contact vias may be disposed therein. The contact vias may include a metal such as tungsten (W), aluminum (Al), or copper (Cu), and tungsten may be applied preferably.

The contact vias may have a columnar shape and may have an inclined side surface having a width decreasing toward the substrate 101.

Contact plugs 150 and 151 may be in contact with a lower surface of the conductive material layer 170, that is, one end and the other end of lower surfaces of the source portion 170S and the drain portion 170D, respectively.

As illustrated in FIG. 5, the contact plugs 150 and 151 may be implemented in multiple layers, and the second contact plugs 151 connected to the source portion 170S and the drain portion 170D, respectively, may be disposed on the first contact plug 150. The first contact plug 150 may have a first length h1, and the first length h1 may be smaller than the second height h2 of an upper surface of the first interlayer insulating layer 160. The contact plugs 150 and 151 connected to the source portion 170S or the drain portion 170D may be in direct contact with an upper surface of the first contact plug 150 and a lower surface of the second contact plug 151, such that a sum of the lengths of the first contact plug 150 and the second contact plug 151 may be substantially equal to the second height h2. In a portion of the contact plugs 150 and 151 connected to the source portion 170S or the drain portion 170D, the first contact plug 150 and the second contact plug 151 may be connected to one another by the upper interconnections 158. In this case, the length of the second contact plug 151 may be smaller than the length of the second contact plug 151 directly connected thereto.

An upper surface of the first contact plug 150 and a lower surface of the second contact plug 151 may be in direct contact with one another, and an upper surface of the second contact plug 151 may be in direct contact with a lower surface of the source portion 170S and the drain portion 170D.

Each of the source portion 170S and the drain portion 170D may further include an ohmic contact layer 172 on at least a portion of a lower surface in contact with an upper surface of the second contact plug 171, but example embodiments thereof are not limited thereto.

As the first switching element SW1 electrically connecting the first pixel region PA1 to the second pixel region PA2 may be physically spaced apart from the substrate 101, leakage due to the blooming effect may be blocked. Accordingly, as the first switching element SW1 is turned on and off only by the voltage of the gate electrode 175, element reliability may be ensured.

Also, the upper interconnections 158 between the first switching element SW1 and the substrate 101 may not be disposed. That is, as the upper interconnections 158 other than the first and second contact plugs 150 and 151 in direct contact with the first switching element SW1 among the upper interconnections 158 are not disposed below the first switching element SW1, particularly, the channel portion 170C, leakage due to unnecessary parasitic capacitance may be reduced.

The first structure L1 may include first bonding structures 166, 169.

The first bonding structures 166, 169 may include the first bonding insulating layer 166 and the first bonding pads 169, and hybrid bonding with the second bonding structure of the second structure L2 may be performed.

The second structure L2 may include a logic substrate 401, a second interconnection structure 430 connected to the second circuit elements 420, a second bonding structure 440 on the second interconnection structure 430, and a logic insulating layer 443 covering the second circuit elements 420 and a second interconnection structure 430 on the logic substrate 401. The second bonding structures 466 and 469 may be connected to the second interconnection structure 430 on the second interconnection structure 430. The second bonding structures 466 and 469 may include a metal material, such as copper (Cu). The second bonding structures 466 and 469 may include bonding pads 469, may be physically bonded to the first bonding pads 169 and may provide an electrical connection path. The second bonding insulating layer 466 may be bonded to the first bonding insulating layer 166 and may provide hybrid bonding. The logic insulating layer 440 may cover the second circuit elements 420 and the second interconnection structure 430.

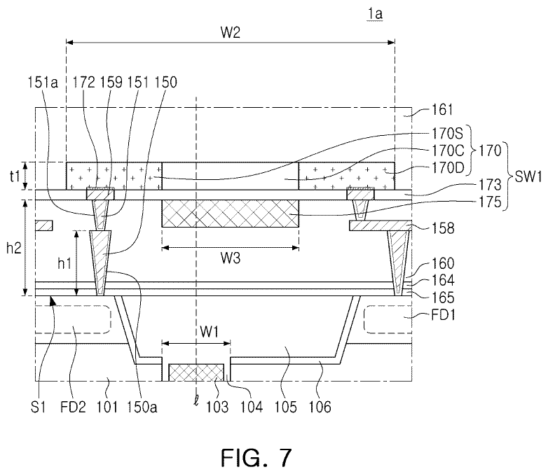

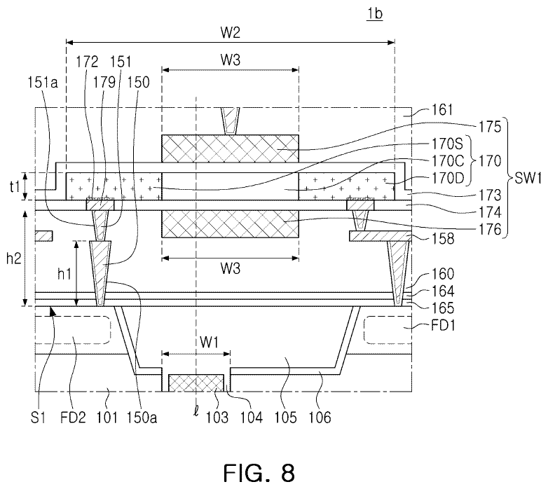

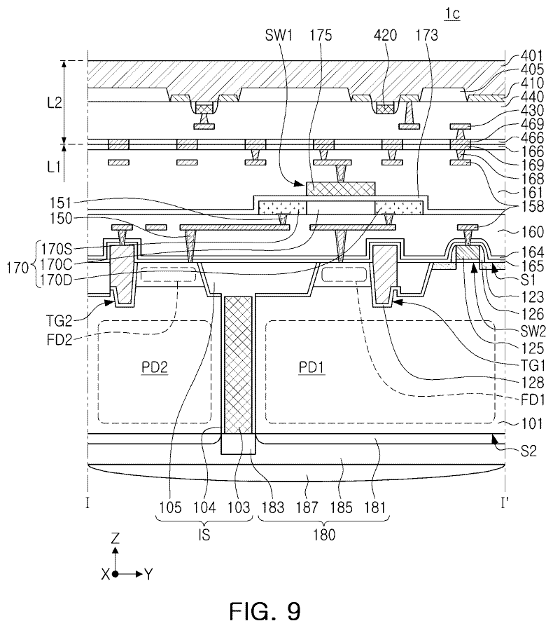

Hereinafter, example embodiments will be described with reference to FIG. 7, FIG. 8 and FIG. 9. FIG. 7 and FIG. 8 are enlarged diagrams of pixel regions of an image sensor according to example embodiments, corresponding to region “B” in FIG. 6, and FIG. 9 is a cross-sectional diagram corresponding to FIG. 5.

Referring to FIG. 7, an image sensor 1a in example embodiments may be the same as the image sensor 1 in FIG. 6, other than the first switching element SW1.

The arrangement of the first switching element SW1 may be the same as the arrangement in FIG. 4. By disposing the first switching element SW1, connecting the two pixel regions PA1 and PA2 to one another, to be spaced apart from the substrate 101, reliability degradation due to electric charges in the substrate 101 may be prevented.

The first switching element SW1 in FIG. 7 may have the gate electrode 175 disposed in the first interlayer insulating layer 160.

As the gate electrode 175 is arranged to horizontally overlap the second contact plug 151, the first switching element SW1 may be formed as a bottom gate transistor. Accordingly, an upper surface of the gate electrode 175 and an upper surface of the first interlayer insulating layer 160 may be coplanar with one another.

An upper gate insulating layer 173 may be disposed on upper surfaces of the gate electrode 175 and the second contact plugs 151, and the first interlayer insulating layer 160. Accordingly, the upper gate insulating layer 173 may be disposed flat without being bent.

A conductive material layer 170 extending perpendicularly to the gate electrode 175 may be disposed on the upper gate insulating layer 173. The conductive material layer 170 may be disposed to cross the PD isolation pattern IS between the first and second pixel regions PA1 and PA2 as illustrated in FIG. 4, one end may be disposed on the first pixel region PA1, and the other end may be disposed on the second pixel region PA2.

The conductive material layer 170 may include a channel portion 170C, which is a portion overlapping an upper portion of the gate electrode 175 corresponding to a gate electrode 175 of a lower portion, and a source portion 170S and a drain portion 170D disposed on both sides of the channel portion 170C.

Here, the source portion 170S and the drain portion 170D may be doped with impurities in high concentration, for example, the source portion 170S may be doped with N-type or P-type impurities. The source portion 170S and the drain portion 170D may be doped from an upper surface to a lower surface.

Contact pads 159 may be disposed between the source portion 170S and the drain portion 170D of the conductive material layer 170 and the second contact plugs 151. The contact pads 159 may be a conductive material, for example, a metal material such as tungsten. The second interlayer insulating layer 161 may be disposed on the conductive material layer 170.

The description of a material of each component of the first switching element SW1 may be the same as in FIG. 3, FIG. 4, FIG. 5, and FIG. 6.

Referring to FIG. 8, an image sensor 1b in example embodiments may be the same as the image sensor 1 in FIG. 6, other than the first switching element SW1.

The arrangement of the first switching element SW1 may be the same as the arrangement in FIG. 4. By disposing the first switching element SW1, connecting the two pixel regions PA1 and PA2 to one another, to be spaced apart from the substrate 101, reliability degradation due to electric charges in the substrate 101 may be prevented.

The first switching element SW1 in FIG. 8 may further include a bottom gate electrode 176 disposed in the first interlayer insulating layer 160.

The bottom gate electrode 176 may be disposed to horizontally overlap the second contact plug 151, and the top gate electrode 175 may be disposed to overlap the bottom gate electrode 176 in the Z-direction, such that the first switching element SW1 may be formed as a dual gate transistor.

An upper surface of the bottom gate electrode 176 and the first interlayer insulating layer 160 may be coplanar with one another.

A bottom gate insulating layer 174 may be disposed on upper surfaces of the bottom gate electrode 176 and the second contact plugs 151, and the first interlayer insulating layer 160. Accordingly, the bottom gate insulating layer 174 may be disposed flat without being bent.

A conductive material layer 170 extending vertically from the bottom gate electrode 176 may be disposed on the bottom gate insulating layer 174. The conductive material layer 170 may be disposed to cross the PD isolation pattern IS between the first and second pixel regions PA2 as illustrated in FIG. 4, one end may be disposed on the first pixel region PA1, and the other end may be disposed on the second pixel region PA2.

The conductive material layer 170 may include a channel portion 170C, which is a portion overlapping the bottom gate electrode 176 corresponding to the bottom gate electrode 175 of a lower portion, and a source portion 170S and a drain portion 170D disposed on both sides of the first channel portion 170C.

Here, the source portion 170S and the drain portion 170D may be highly doped with impurities, and may be doped with, for example, N-type or P-type impurities. The source portion 170S and the drain portion 170D may be doped from an upper surface to a lower surface.

Contact pads 179 may be disposed between the source portion 170S and the drain portion 170D of the conductive material layer 170 and the second contact plugs 151. The contact pads 179 may be a conductive material, for example, a metal material such as tungsten. The second interlayer insulating layer 161 may be disposed on the conductive material layer 170.

The top gate insulating layer 173 may be disposed while covering the conductive material layer 170, and the top gate electrode 175 overlapping the channel portion 170C may be disposed on the top gate insulating layer 173. The configurations of the top gate insulating layer 173 and the top gate electrode 175 may be the same as in FIG. 6.

A material of each component of the first switching element SW1 may be the same as in FIG. 3, FIG. 4, FIG. 5, and FIG. 6.

Referring to FIG. 9, an image sensor 1c in example embodiments may be the same as the image sensor 1 in FIG. 5, other than the first switching element SW1.

The stacking configuration of the first switching element SW1 may be the same as in FIG. 6. By disposing the first switching element SW1, connecting the two pixel regions to one another, to be spaced apart from the substrate 101, reliability degradation due to electric charges in the substrate 101 may be prevented.

The first switching element SW1 in FIG. 9 may be disposed so as not to overlap the PD isolation pattern IS, particularly the boundary isolation pattern 103a, in the Z-direction. To this end, interconnection layers 156 may be further disposed between the first contact plug 150 and the second contact plug 151.

The interconnection layers 156 may connect between an upper surface of the first contact plug 150 and a lower surface of the second contact plug 151, and the first contact plug 150 and the second contact plug 151 may be disposed so as to be offset without overlapping in the Z-direction and to be electrically connected to one another.

Accordingly, the first switching element SW1 may not be disposed to physically overlap the PD isolation pattern IS and the boundary isolation pattern 103a between the first pixel region PA1 and the second pixel region PA2 in the Z-direction, and may be shifted to the first pixel region PA1 having a greater area. Accordingly, the degree of freedom in the position of the first switching element SW1 may be increased, the components may be disposed in various shapes.

In the description above, the first switching element SW1 may be implemented as a stacked transistor such that the source portion 170S and the drain portion 170D may be connected across the first pixel region PA1 and the second pixel region PA2, respectively, but example embodiments thereof is not limited thereto, and the entirety of circuit elements shared in the pixel regions may be implemented as stacked transistors.

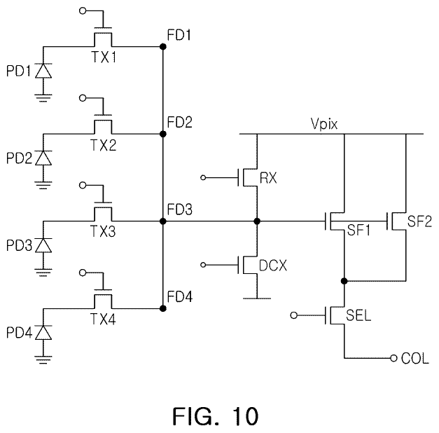

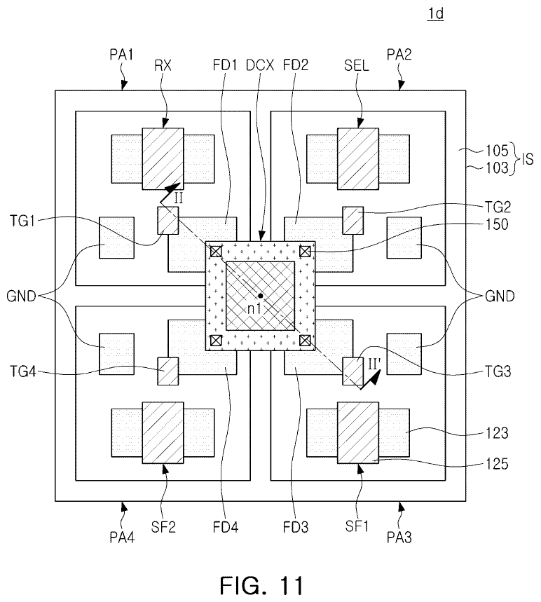

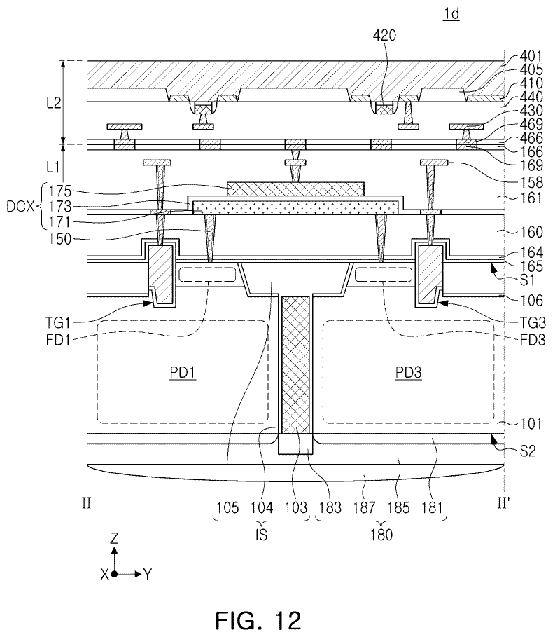

FIG. 10 is a circuit diagram illustrating a pixel circuit according to example embodiments. FIG. 11 is a plan diagram illustrating a pixel circuit according to example embodiments. FIG. 12 is a cross-sectional diagram illustrating the image sensor cut along ‘II-II’in FIG. 11.

Referring to FIG. 10, each of the pixel PX may include four photodiodes PD1-PD4, four transfer transistors TX1-TX4, four floating diffusion regions FD1-FD4, a reset transistor RX, a select transistor SEL, a dual conversion gain transistor DCG, and source follower transistors SF1 and SF2.

The first to fourth photodiodes PD1-PD4 may be connected to the first to fourth transfer transistors TX1-TX4, respectively, and may be driven by the first and second source follower transistors SF1 and SF2.

Each of the pixel PX may be structured as one pixel region PA, and one pixel region PA may include four sub-pixel regions PA1-PA4 as illustrated in FIG. 11. The four sub-pixel regions PA1-PA4 may be arranged in a 2×2 form. The first sub-pixel region PA1 may include a first transfer transistor TX1 including a first photodiode PD1, a first floating diffusion region FD1, and a first transfer transistor TX1. In the first pixel region PA1, the first photodiode PD1 may be connected to the first floating diffusion region FD1 through the first transfer transistor TX1. Similarly, the second to fourth photodiodes PD2-PD4 of the second to fourth sub-pixel regions PA2-PA4 may be connected to the second to fourth floating diffusion region FD2-FD4 through the second to fourth transfer transistors TX2-TX4 including the second to fourth transfer transistors TX2-TX4, respectively.

In the four adjacent sub-pixel regions PA1-PA4, the first to fourth floating diffusion regions FD1-FD4 may be configured physically isolated from one another by a second isolation pattern 105 and may be electrically connected to one another by a dual conversion gain transistor DCX.

When electric charge is stored in the floating diffusion region by the transfer transistors TX1-TX4 being turned on, the dual conversion gain transistor DCX may store electric charge of the floating diffusion region FD1-FD4 in the dual conversion gain transistor DCX by turning the dual conversion gain transistor DCX on and off, thereby operating as a capacitor. Accordingly, the electric charge accumulation ability of the floating diffusion regions FD1-FD4 may be improved.

To this end, the dual conversion gain transistor DCX may be configured to extend from centers n1 of the four sub-pixel regions PA1-PA4 to the four sub-pixel regions PA1-PA4, respectively. For example, as illustrated in FIG. 11, the dual conversion gain transistor DCX may be configured to pass through the center n1 regions of the four sub-pixel regions PA1-PA4 and to overlap each of the four sub-pixel regions PA1-PA4 by a predetermined area.

Four sub-pixel regions PA1-PA4 adjacent to one another may share a pixel circuit, and the shared pixel circuit may include a dual conversion gain transistor DCX, a reset transistor RX, first and second source follower transistors SF1 and SF2, and select transistor SEL.

For example, each of the four sub-pixel regions PA1-PA4 may further include one transistor in addition to the transfer gates TG1 and TG2 of the transfer transistors TX1 and TX2. Two of the four transistors included in the four sub-pixel regions PA1-PA4 may be configured to be connected to one another in parallel, thereby providing the first and second source follower transistors SF1 and SF2, one of the other two transistors may be configured to be provided as the select transistor SEL, the other may be configured to be provided as the reset transistor RX, and the dual conversion gain transistor DCX may be spaced apart from the substrate 101, may be disposed in an upper portion of the substrate 101 and may be shared.

Referring to FIG. 12, an image sensor 1d may include a first structure L1 corresponding to the pixel array 10 and a second structure L2 corresponding to the logic circuit 20 bonded thereto. Most of the components of the first structure L1 and the second structure L2 may be the same as those of the image sensor 1 in FIGS. 1 to 6.

The image sensor 1d in FIG. 12 may include contact plugs 150 connected to the first to fourth floating diffusion regions FD1-FD4 in the first to fourth pixel regions PA1-PA4.

The contact plugs 150 may be formed to penetrate the first interlayer insulating layer 160, and the dual conversion gain transistor DCX may be disposed on the first interlayer insulating layer 160.

The dual conversion gain transistor DCX may be disposed to overlap the center n1 of the pixel region PA, that is, the PD isolation pattern IS, and may have a quadrangular or circular shape in which at least a portion overlaps each pixel region PA.

The dual conversion gain transistor DCX may include a conductive material layer 171, an upper gate insulating layer 173, and a gate electrode 175.

The conductive material layer 171 may represent the shape of the dual conversion gain transistor DCX, may overlap the gate electrode 175 in the Z-direction, and may have an area greater than that of the gate electrode 175. Accordingly, the conductive material layer 171 may be represented in a similar shape concentric with the gate electrode 175 on a plane.

Differently from the conductive material layer 170 in FIG. 6, the conductive material layer 171 may not include the source portion and the drain portion and may be doped with impurities at a low concentration. Accordingly, when a large gate voltage is applied to the gate electrode 175, and may thus function as a capacitor drawing in and storing electric charge of the connected first to fourth floating diffusion regions FD1-FD4.

To this end, the contact plugs 150 connected to the first to fourth floating diffusion regions FD1-FD4, respectively, may be simultaneously connected to the conductive material layer 171.

In this case, the contact plugs 150 may be connected to the conductive material layer 171 not overlapping the gate electrode 175.

A material of the upper gate insulating layer 173 and the gate electrode 175 may be the same as that in FIG. 6, and the second interlayer insulating layer 161 may be disposed while covering the dual gate transistor DCX.

As described above, the dual gate transistor DCX shared by the four pixel regions PA1-PA4 may also be spaced apart from the substrate 101 and may be formed to include a semiconductor different from the substrate 101 on the first interlayer insulating layer 160.

In FIG. 10, FIG. 11, and FIG. 12, the dual conversion gain transistor DCX may be arranged as a stacked transistor, but an image sensor including a stacked transistor, which is a dual conversion gain transistor DCX in FIGS. 2 to 9, and including a switching element SW1, which is a stacked transistor, may be implemented. Also, transistors other than the transfer transistor TX among the other circuit elements may also be implemented as stacked transistors depending on a pixel circuit design.

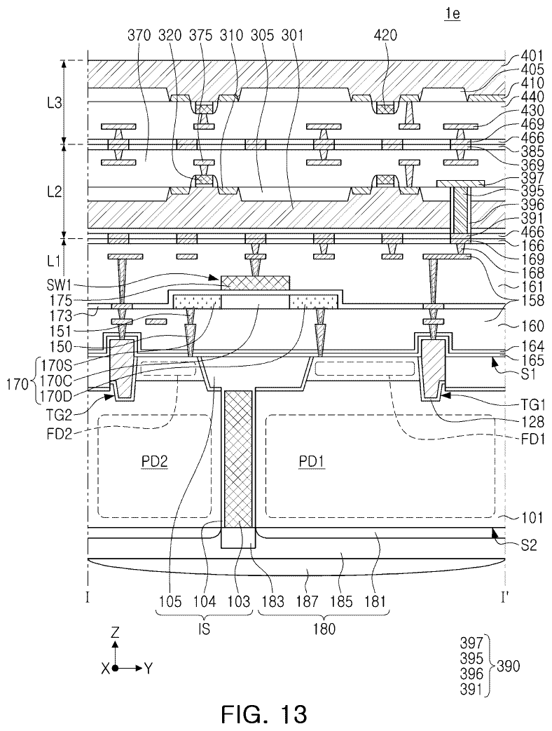

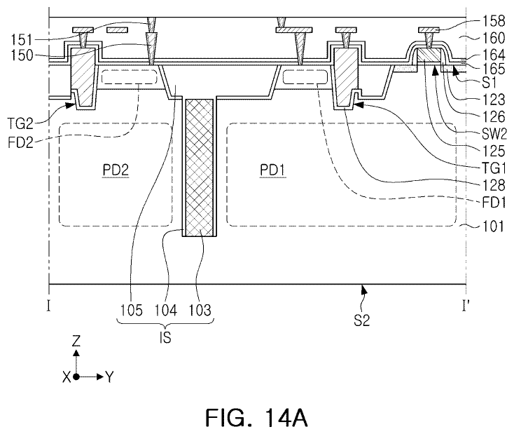

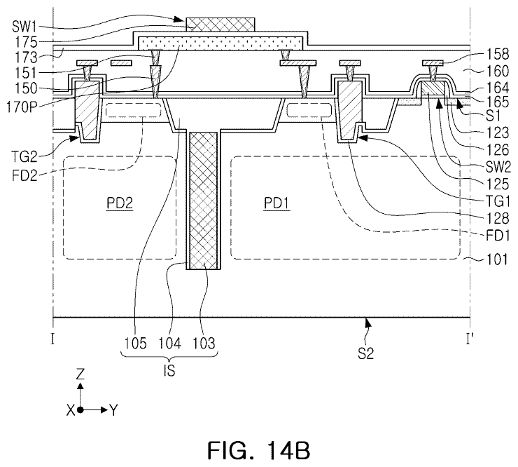

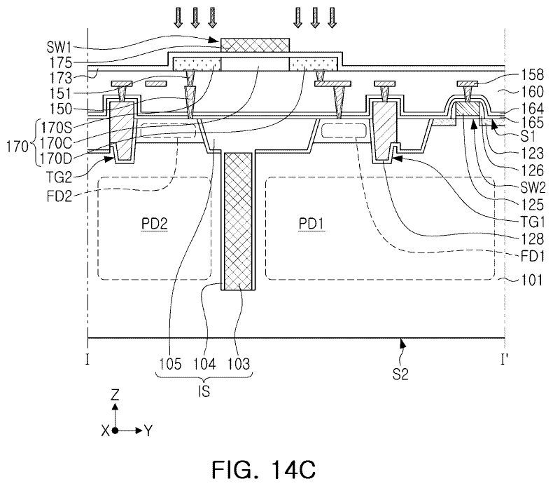

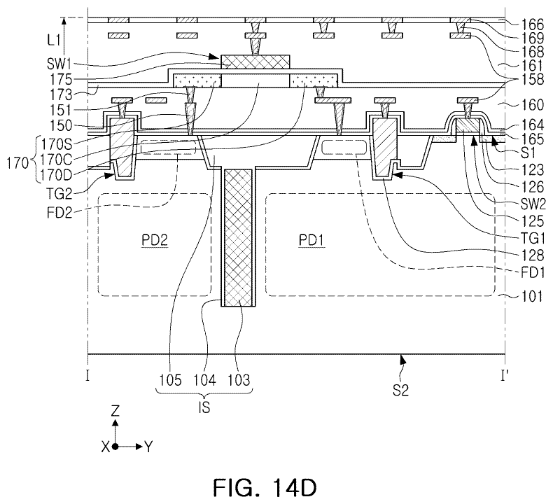

FIG. 13 is a cross-sectional diagram illustrating an image sensor according to example embodiments.

Referring to FIG. 13, an image sensor 10e may include a third structure L3 included in a logic circuit 20, a second structure L2 disposed below the third structure L3 and included in a pixel array 10, and a first structure L1 therebelow.

The image sensor 10e may include a first structure L1 including a first substrate 101, a second structure L2 including a second substrate 301, and a third structure L3 including a third substrate 401. The third structure L3 may be configured as a logic chip including a logic circuit 20, and the second and first structures L1 and L2 may be configured as an image sensor structure including a plurality of pixels PX. The first structure L1 may include a first switching element SW1 and a transfer gate TG, and the second structure L2 may include transistors other than the first switching element SW1 and the transfer gate TG.

The first structure L1 may include the first switching element SW1, the transfer transistors TG1-TG2, the floating diffusion regions FD1 and FD2 and the photodiodes PD1 and PD2 among the structures of the first substrate 101 described in FIGS. 1 to 6, and may include the first switching element SW1 between the first interlayer insulating layer 160 and the second interlayer insulating layer 161. The first bonding structures 166 and 169 may be included in an upper portion of the second interlayer insulating layer 161. The drain portion 170D and the source portion 170S of the first switching element SW1 may be connected to the first and second floating diffusion regions FD1 and FD2, respectively. The first structure L1 may include the entirety of the optical units 180 on the other surface of the first substrate 101, and the description thereof may be the same as in FIG. 5.

The second structure L2 may include a second substrate 301 having a lower surface facing the first structure L1 and an upper surface opposing the lower surface, an element isolation film 305 defining an active region 310 in the second substrate 301, circuit elements 320 on an upper surface of the second substrate 301, an interconnection region 375 connected to the circuit elements 320, a second lower bonding structure 390 and 393 on a lower surface of the second substrate 301, a second upper bonding structure 385 on an upper surface of the second substrate 301, a second lower insulating layer 380 on a lower surface of the second substrate 301, and a second upper insulating layer 370 on an upper surface of the second substrate 301.

The second circuit elements 320 may include transistors disposed therein, other than the transfer gates TG1 and TG2 and the first switching element SW1. The interconnection region 375 may be disposed between the second substrate 301 and the third structure L3. The interconnection region 375 may apply an electrical signal to the second circuit elements 320. The second upper bonding structure 385 and 369 may be a structure for bonding with the third structure L3. The second upper bonding structure 385 and 369 may include a metal material such as copper (Cu), or may be implemented as a bonding insulating layer.

The second lower insulating layer 380 may include a bonding insulating layer 393 having a predetermined thickness from a lower surface. The bonding insulating layer 393 may be for dielectric-dielectric bonding with the bonding insulating layer 166 of the first structure L1.

The second lower bonding structure 390 may be a structure for bonding with the first structure L1. The second lower bonding structure 390 may include a third bonding pad 391 on a lower surface of a second substrate 301, a landing structure 397 disposed on an upper surface of the second substrate 301, a third bonding via 395 disposed between the third bonding pad 391 and the landing structure 397, and a side surface insulating layer 396 disposed between the second substrate 301 and the third bonding via 395. The third bonding pad 391 may include a metal material such as copper (Cu), and the third bonding via 395 may include a metal material such as copper (Cu), tungsten (W), or the like. The third bonding pad 391 may include the same metal material as that of the third bonding via 395, but example embodiments thereof is not limited thereto.

The third structure L3 may include a third substrate 401, a third interconnection structure 430 connected to third circuit elements 420, third circuit element isolation pattern 405, a third bonding structure 440 on the third interconnection structure 430, and a logic insulating layer 440 covering the third circuit elements 420 and the third interconnection structure 430 on the third substrate 401. The third bonding structures 469 and 466 may be connected to the third interconnection structure 430 on the interconnection structure 430. The third bonding structures 469 and 466 may include a metal material, such as copper (Cu). The third bonding structures 469 and 466 may include a bonding pad 469, thereby providing an electrical connection path. The logic insulating layer 440 may cover the third circuit elements 420 and the third interconnection structure 430, and may cover a portion of the third bonding structures 469 and 466.

As described above, by dividing the image sensor chip including the pixel array as two structures L1 and L2, and electrically connecting the components by performing hybrid bonding between the structures L1 and L2 by the bonding structure 390, the image sensor le by hybrid bonding of the three structures L1, L2, and L3 may be implemented.

Hereinafter, a method of manufacturing an image sensor according to example embodiments will be described with reference to FIG. 14A, FIG. 14B, FIG. 14C, and FIG. 14D. FIG. 14A, FIG. 14B, FIG. 14C, and FIG. 14D are cross-sectional diagrams illustrating a method of manufacturing a pixel array of the image sensor 1 in FIG. 5.

Referring to FIG. 14A, a substrate 101 may be prepared, a second isolation pattern 105 and a first isolation pattern 103 may be formed from one surface S1 of the substrate 101, and circuit elements may be formed on one surface S1 of the substrate 101.

Specifically, photodiodes PD1-PD2 may be formed in the substrate 101, and a second isolation pattern 105 defining an active region 123 may be formed by forming a trench on one surface S1 of the substrate 101 and burying the trench. In this case, an oxide film may be formed on the inner wall of the trench, and a nitride film may be formed as a liner 106.

A portion of the second isolation pattern 105 may be opened, a deep trench for forming a first isolation pattern 103 may be formed, and the deep trench may be formed in an octagonal columnar shape or a quadrangular columnar shape for partitioning the sub-pixel region PA1-PA2.

That is, a deep trench may be formed from a bottom surface of the second isolation pattern 105, a trench liner 104 may be formed, and a first isolation pattern 103, which is a conductive material, may be formed in the center. As the conductive material, polysilicon may be stacked. Thereafter, a trench may be buried in the second isolation pattern 105, and a device isolation insulating film may be formed.

In this case, an insulating material may be over-deposited, and may be flattened until one surface of the substrate 101 is exposed, thereby forming the second isolation pattern 105.

Transfer gates TG1-TG2 and gate structures 125, 126, and 128 of transistors may be formed. First, an opening may be formed to open a region corresponding to the transfer gates TG1-TG2, and the depth of the opening may vertically extend into the substrate 101 to be close to the photodiode PD1-PD2.

A gate insulating layer 128 may be formed on an internal side surface of the opening and one surface S1 of the substrate 101. The forming the gate insulating layer 128 may include removing a surface oxide film by performing a cleaning process as a preprocess, and depositing a silicon oxide film as the gate insulating layer 128. In this case, the gate insulating layer 128 may be formed entirely on the other region of one surface S1 of the substrate 101 in which transistors are formed, specifically, rather than on the second isolation pattern 105. The opening may be buried and a conductive layer may be formed. In this case, the conductive layer may be formed by stacking polysilicon, and may be formed to have a conductive layer by depositing and ion-implanting polysilicon. In this case, the conductive layer may be over-deposited on the entire one surface S1 of the substrate 101 such that the conductive layers of other transistors may also be formed simultaneously.

By patterning the conductive layer, the transfer gates TG1-TG2 and the gate electrode layer 125 of other transistors may be formed simultaneously. In this case, the gate insulating layer 128 may remain in a lower portion of each gate electrode layer 125, and the gate spacer 126 may be formed on the side surface of the gate electrode 125.

The first conductivity-type impurities may be ion-implanted on the gate electrode 125 and the gate spacer 126.

For example, as the first conductivity-type impurities, impurities such as P and As may be injected. In this case, the first conductivity-type impurities may also be injected into the floating diffusion regions FD1 and FD2, and the injection concentrations may be different from one another, but example embodiments thereof is not limited thereto. Also, the ground region may also be formed by injecting impurities of different conductivity-types.

The substrate insulating layer 165 may be formed, and activation, that is, diffusion of injected impurity ions may be performed by annealing.

Also, after annealing, a nitride film, which is an upper insulating layer 164, may be formed to protect the elements. In this case, the substrate insulating layer 165 and the upper insulating layer 164 may be formed conformally according to the shape of each element.

The first interlayer insulating layer 160 may be formed, and contact plugs 150 and 151 penetrating the first interlayer insulating layer 160 and in contact with each element may be formed.

The contact plugs 150 and 151 may be performed by forming a via hole, forming diffusion barriers 150a and 151a, depositing a metal material to be buried, and flattening the material. The diffusion barrier 150a and 151a may be TiN, TaN, or the like, and the metal material may include a conductive material such as W, Al, Cu, or the like.

Referring to FIG. 14B, a preliminary conductive material layer 170P having a predetermined area may be formed on an upper surface of the first interlayer insulating layer 160.

The preliminary conductive material layer 170P may include a material different from the substrate 101, and as an example, the preliminary conductive material layer 170P may include at least one of IGZO, ZnO, In₂O₃, TiO₂, or the like, as an oxide semiconductor, or may include polysilicon or graphene. When the conductive material layer 170 may include graphene, the conductive material layer 170 may be implemented to have a thickness less than when another material is used.

The preliminary conductive material layer 170P not doped may be formed by depositing to have a first thickness t1. When the preliminary conductive material layer 170P includes an oxide semiconductor, for example, IGZO, low-temperature deposition may be performed to protect the circuit elements and substrate 101 in a lower portion.

The upper gate insulating layer 173 may be deposited on the first interlayer insulating layer 160 while covering the preliminary conductive material layer 170P. The upper gate insulating layer 173 may include silicon oxide or silicon oxynitride.

The gate electrode 175 may be deposited on the upper gate insulating layer 173. The gate electrode 175 may include the same material as that of the gate electrode 125 on the substrate 101, may include doped polysilicon, and may include other metals.

Referring to FIG. 14C, the source portion 170S and the drain portion 170D may be formed by ion-implanting conductive impurities using the gate electrode 175 as a mask pattern.

The source portion 170S and the drain portion 170D may be doped from an upper surface to a lower surface of the conductive material layer 170 by overdoping conductive impurities, and an undoped channel region 170C may be formed in the region overlapping the gate electrode 125.

Referring to FIG. 14D, upper interconnections 158 may be formed, and bonding structures 166 and 169 may be formed, and as in FIG. 5, a second structure L2 may be formed on an upper surface, and an optical unit 180 may be formed on the other surface S2 of the substrate 101, thereby forming the image sensor 1 in FIG. 5.

While the example embodiments have been illustrated and described above, it will be configured as apparent to those skilled in the art that modifications and variations could be made without departing from the scope of the present disclosure as defined by the appended claims.

What is claimed is:

1. An image sensor, comprising:
a substrate including pixel regions each including a photodiode;
a floating diffusion region disposed in each of the pixel regions on one surface of the substrate and configured to store electric charge transferred from the photodiode;
circuit elements configured to transmit a photoelectric signal according to the electric charge of the floating diffusion region; and
a first interlayer insulating layer covering the floating diffusion region on the one surface of the substrate,
wherein at least one of the circuit elements includes:
a conductive material layer disposed on the first interlayer insulating layer and including a source region and a drain region; and
a gate electrode disposed between the source region and the drain region on the conductive material layer, and
wherein the source region is connected to one pixel region among the pixel regions, and the drain region is connected to another pixel region among the pixel regions.

2. The image sensor of claim 1, wherein the source region and the drain region of the conductive material layer include a semiconductor including first conductivity-type impurities.

3. The image sensor of claim 1, further including:
a first isolation pattern configured to isolate the photodiode in the substrate,
wherein the conductive material layer vertically overlaps at least a portion of the first isolation pattern.

4. The image sensor of claim 1, wherein a lower surface of the conductive material layer is spaced apart from the one surface of the substrate by a predetermined distance.

5. The image sensor of claim 1, wherein the conductive material layer includes a material different from a material of the substrate.

6. The image sensor of claim 1, wherein the conductive material layer includes oxide semiconductor or polysilicon, and the substrate includes single crystal silicon.

7. The image sensor of claim 1, wherein at least one of the circuit elements connects or blocks the floating diffusion regions of neighboring pixel regions.

8. The image sensor of claim 7, wherein the neighboring pixel regions have different areas.

9. The image sensor of claim 7,
wherein the neighboring pixel regions include:
a first pixel region including a first photodiode; and
a second pixel region including a second photodiode and having an area less than an area of the first pixel region, and
wherein the drain region of the conductive material layer is connected to a first floating diffusion region of the first pixel region, and the source region of the conductive material layer is connected to a second floating diffusion region of the second pixel region.

10. The image sensor of claim 1,
further comprising a contact plug electrically connected to the circuit elements, and
wherein the contact plug is in contact with a lower surface of the conductive material layer.

11. The image sensor of claim 1, wherein an interconnection structure is not disposed in the first interlayer insulating layer between the conductive material layer and the substrate.

12. The image sensor of claim 1, wherein the gate electrode is positioned at a level higher than a level of an upper surface of the conductive material layer.

13. The image sensor of claim 1,
wherein the image sensor includes a first isolation pattern configured to isolate the photodiode in the substrate, and
wherein the conductive material layer is offset from the first isolation pattern between two pixel regions electrically connected to the source region and the drain region.

14. The image sensor of claim 1, wherein the other circuit element of the circuit elements is configured as a dual conversion gain transistor including the gate electrode and the conductive material layer, in which the conductive material layer thereof is commonly connected to floating diffusion regions of neighboring pixel regions.

15. An image sensor, comprising:
a substrate including a first pixel region including a first photodiode and a second pixel region including a second photodiode;
a first isolation pattern defining the first and second pixel regions in the substrate;
a first floating diffusion region configured to store electric charge transferred from the first photodiode in the first pixel region on one surface of the substrate;
a second floating diffusion region configured to store electric charge transferred from the second photodiode in the second pixel region on the one surface of the substrate;
a source follower transistor configured to amplifying electric charge of the first and second floating diffusion regions on the one surface of the substrate and to transmit a signal;
a first interlayer insulating layer covering the source follower transistor and the first and second floating diffusion regions on the one surface of the substrate; and
a switching element disposed on the first interlayer insulating layer and vertically overlapping the first isolation pattern between the first pixel region and the second pixel region,
wherein the switching element includes a gate electrode and a conductive material layer, and the conductive material layer includes a source region and a drain region on both sides of the gate electrode, and
wherein the drain region and the source region are electrically connected to the first and second floating diffusion regions, respectively.

16. The image sensor of claim 15, wherein an area of the first pixel region is greater than an area of the second pixel region.

17. The image sensor of claim 15, wherein the conductive material layer crosses the first isolation pattern between the first pixel region and the second pixel region, the drain region on one side is disposed on the first pixel region, and the source region on the other side is disposed on the second pixel region.

18. The image sensor of claim 15, wherein a lower surface of the conductive material layer is physically spaced apart from one surface of the substrate.

19. The image sensor of claim 15, wherein the source region and the drain region of the conductive material layer are doped with conductivity-type impurities from an upper surface to a lower surface.

20. An image sensor, comprising:
a pixel array including a plurality of pixel regions arranged in a direction parallel to one surface of a substrate, each of the plurality of pixel regions including at least one photodiode in the substrate, a color filter disposed on the other surface opposite to the one surface of the substrate and at least one element disposed on the one surface; and
a logic circuit configured to obtain a pixel signal from the plurality of pixel regions,
wherein the pixel array includes:
a floating diffusion region disposed in each of the plurality of pixel regions and configured to store an electric charge transferred from the photodiode on the one surface of the substrate;
the elements configured to transmit a photoelectric signal according to electric charge of the floating diffusion region; and
a first interlayer insulating layer covering the floating diffusion region on the one surface of the substrate,
wherein at least one of the elements includes:
a conductive material layer disposed on the first interlayer insulating layer and including a source region and a drain region; and
a gate electrode disposed between the source region and the drain region on the conductive material layer, and
wherein the source region is connected to one pixel region among the plurality of pixel regions, and the drain region is connected to another pixel region among the plurality of pixel regions.
